(19) United States
(12) Patent Application Publication
(10) Pub. No.: US 2024/0429103 A1
(43) Pub. Date: Dec. 26, 2024

(54) BACKSIDE CONTACT MITIGATING CONTACT TO GATE SHORT

(71) Applicant: International Business Machines Corporation, Armonk, NY (US)

(72) Inventors: Tao Li, Slingerlands, NY (US); Joe Lee, Niskayuna, NY (US); Ruilong Xie, Niskayuna, NY (US); Kisik Choi, Watervliet, NY (US)

(21) Appl. No.: 18/340,969

(22) Filed: Jun. 26, 2023

(51) Int. Cl. H01L 21/8234; H01L 21/768; H01L 23/528; H01L 27/088; H01L 29/78

(52) U.S. Cl. CPC H01L 21/823475; H01L 21/76897; H01L 21/823418; H01L 21/823431; H01L 23/5286; H01L 27/0886; H01L 29/785

(57) ABSTRACT

A semiconductor device includes a semiconductor substrate including shallow trench isolation (STI) regions, a semiconductor fin between the STI regions, and a STI liner on an upper surface of the STI regions. A STI layer is in each of the STI regions, and includes a liner opening exposing a portion of the STI layer. A source/drain is on a sidewall of the semiconductor fin. A multi-stage backside contact is on the source/drain and contacting the portion of the STI layer via the liner opening.

### BACKGROUND

The present invention generally relates to fabrication methods and resulting structures for semiconductor devices. More specifically, the present invention relates to a semiconductor device fabrication method with backside direct contact formation.

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### SUMMARY

According to a non-limiting embodiment, A semiconductor device includes a semiconductor substrate including shallow trench isolation (STI) regions, a semiconductor fin between the STI regions, and a STI liner on an upper surface of the STI regions. A STI layer is in each of the STI regions, wherein the STI layer includes a liner opening exposing a portion of the STI layer. A source/drain is on a sidewall of the semiconductor fin. A multi-stage backside contact is on the source/drain and contacting the portion of the STI layer via the liner opening.

According to another non-limiting embodiment, a method of fabricating a semiconductor device comprises etching a semiconductor substrate to form a semiconductor fin between shallow trench isolation (STI) regions; forming a STI liner on an upper surface of the STI regions and on sidewalls of the semiconductor fin, and etching a portion of the semiconductor fin to exposed a portion of the semiconductor substrate defining source/drain regions. The method further comprises forming backside contact placeholders in the source/drain regions and on the exposed portion of the semiconductor substrate, and forming source/drains on an upper surface of the backside contact placeholders. The method further comprises replacing a portion of the semiconductor substrate covering the backside contact placeholders and the STI liner with a backside patterning stack. The method further comprises performing a multi-stage backside contact patterning process to selectively remove portions of the backside patterning stack without removing the STI liner to form a multi-stage backside contact trench; and filling the multi-stage backside contact trench with a conductive material to form a multi-stage backside contact.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a plan view of an example nanosheet transistor indicating a Y1 cross-section location, a Y2 cross-section location, and an X cross section location for the following figures, in accordance with embodiments of the present disclosure.

FIG. 2 illustrates a cross-sectional view of an example semiconductor device at an intermediate stage in the fabrication process, in accordance with embodiments of the present disclosure.

FIGS. 3A, 3B and 3C illustrate cross-sectional views of the semiconductor device of FIG. 2 following additional fabrication operations according to embodiments of the present disclosure.

FIGS. 4A, 4B and 4C illustrate cross-sectional views of the semiconductor device of FIGS. 3A, 3B and 3C following additional fabrication operations according to embodiments of the present disclosure.

FIGS. 5A, 5B and 5C illustrate cross-sectional views of the semiconductor device of FIGS. 4A, 4B and 4C following additional fabrication operations according to embodiments of the present disclosure.

FIGS. 6A, 6B and 6C illustrate cross-sectional views of the semiconductor device of FIGS. 5A, 5B and 5C following additional fabrication operations according to embodiments of the present disclosure.

FIGS. 7A, 7B and 7C illustrate cross-sectional views of the semiconductor device of FIGS. 6A, 6B and 6C following additional fabrication operations according to embodiments of the present disclosure.

FIGS. 8A, 8B and 8C illustrate cross-sectional views of the semiconductor device of FIGS. 7A, 7B and 7C following additional fabrication operations according to embodiments of the present disclosure.

FIGS. 9A, 9B and 9C illustrate cross-sectional views of the semiconductor device of FIGS. 8A, 8B and 8C following additional fabrication operations according to embodiments of the present disclosure.

FIGS. 10A, 10B and 10C illustrate cross-sectional views of the semiconductor device of FIGS. 9A, 9B and 9C following additional fabrication operations according to embodiments of the present disclosure.

FIGS. 11A, 11B and 11C illustrate cross-sectional views of the semiconductor device of FIGS. 10A, 10B and 10C following additional fabrication operations according to embodiments of the present disclosure.

FIGS. 12A, 12B and 12C illustrate cross-sectional views of the semiconductor device of FIGS. 11A, 1B and 11C following additional fabrication operations according to embodiments of the present disclosure.

FIGS. 13A, 13B and 13C illustrate cross-sectional views of the semiconductor device of FIGS. 12A, 12B and 12C following additional fabrication operations according to embodiments of the present disclosure.

FIGS. 14A, 14B and 14C illustrate cross-sectional views of the semiconductor device of FIGS. 13A, 13B and 13C following additional fabrication operations according to embodiments of the present disclosure.

FIGS. 15A, 15B and 15C illustrate cross-sectional views of the semiconductor device of FIGS. 14A, 14B and 14C following additional fabrication operations according to embodiments of the present disclosure.

FIGS. 16A, 16B and 16C illustrate cross-sectional views of the semiconductor device of FIGS. 15A, 15B and 15C following additional fabrication operations according to embodiments of the present disclosure.

FIGS. 17A, 17B and 17C illustrate cross-sectional views of the semiconductor device of FIGS. 16A, 16B and 16C following additional fabrication operations according to embodiments of the present disclosure.

FIGS. 18A, 18B and 18C illustrate cross-sectional views of the semiconductor device of FIGS. 17A, 17B and 17C following additional fabrication operations according to embodiments of the present disclosure.

FIGS. 19A, 19B and 19C illustrate cross-sectional views of the semiconductor device of FIGS. 18A, 18B and 18C following additional fabrication operations according to embodiments of the present disclosure.

FIGS. 20A, 20B and 20C illustrate cross-sectional views of the semiconductor device of FIGS. 19A, 19B and 19C following additional fabrication operations according to embodiments of the present disclosure.

FIGS. 21A, 21B and 21C illustrate cross-sectional views of the semiconductor device of FIGS. 20A, 20B and 20C following additional fabrication operations according to embodiments of the present disclosure.

FIGS. 22A, 22B and 22C illustrate cross-sectional views of the semiconductor device of FIGS. 21A, 21B and 21C following additional fabrication operations according to embodiments of the present disclosure.

FIGS. 23A, 23B and 23C illustrate cross-sectional views of the semiconductor device of FIGS. 22A, 22B and 22C following additional fabrication operations according to embodiments of the present disclosure.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, a field effect transistor (FET) typically has a source, a channel and a drain where current flows from the source to the drain as well as a gate that controls the flow of current through the device channel. FETs can have a variety of different structures. For example, FETs have been fabricated with the source, channel and drain formed in a substrate material itself, where the current flows horizontally (i.e., in the plane of the substrate). As another example, FinFETs have been formed with the channel extending outwardly from the substrate, but where the current also flows horizontally from the source to the drain. The channel for the FinFET can be an upright slab of thin rectangular silicon (Si), commonly referred to as the fin with a gate on the fin, as compared to a metal-oxide-semiconductor FET (MOSFET) with a single gate parallel with the plane of the substrate. Depending on doping of the source and drain, an n-doped FET (nFET) or a p-doped FET (pFET) can be formed. Two FETs also can be coupled to form a complementary metal-oxide-semiconductor (CMOS) device, where a p-channel MOSFET and n-channel MOSFET are coupled together.

In certain logic circuits in which FETs are employed, it is often the case that a self-aligned backside contact is needed to mitigate poor overlay margin at a backside of a wafer. However, known self-aligned backside contacts capable of mitigating poor overlay margins are formed with an increased height that arranges the upper surface of the self-aligned backside contact near the gate and causes backside contact to gate short concerns.

Various embodiments of the present disclosure provide a method and resulting semiconductor device that establishes a multi-stage backside contact, which includes an overlap region that reduces the distance between the backside contact and the gate. As a result, the method and resulting semiconductor device described herein mitigates the backside contact to gate short concerns associated with known backside gate contacts.

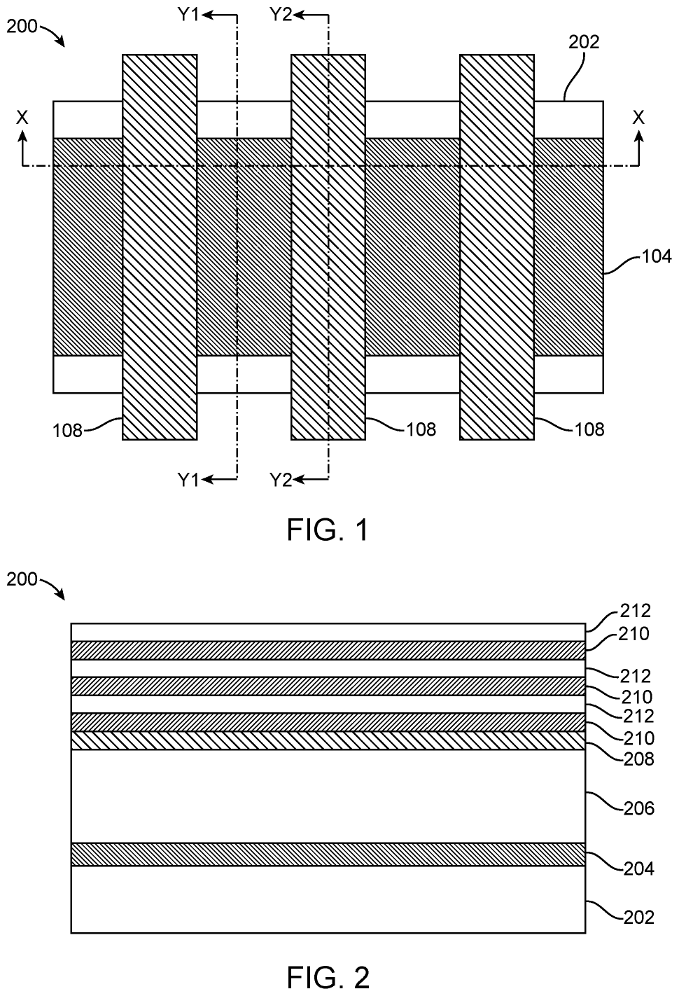

With reference now to the figures, FIG. 1 depicts a plan view of an example semiconductor device 200 indicating a Y1 cross-section location, a Y2 cross-section location, and an X cross section location for the following figures, in accordance with embodiments of the present disclosure. The semiconductor device 200 includes substrate with one or more fin regions 104 at which a semiconductor fin will be formed and one or more gate regions 108 at which a metal gate will be formed and will cross the fin region 104. FIG. 1 also shows the location of the cross-sectional cuts that are illustrated in the figures described herein. Cut Y1 runs across the nanosheet transistors in the source/drain epitaxy region, cut Y2 runs across the nanosheet transistors in the gate region, and cut X runs along a length of a semiconductor substrate 202 and crosses three gate regions 108. The subsequent figures show cross-sectional views along these cuts Y1, Y2, and X after particular fabrication operations.

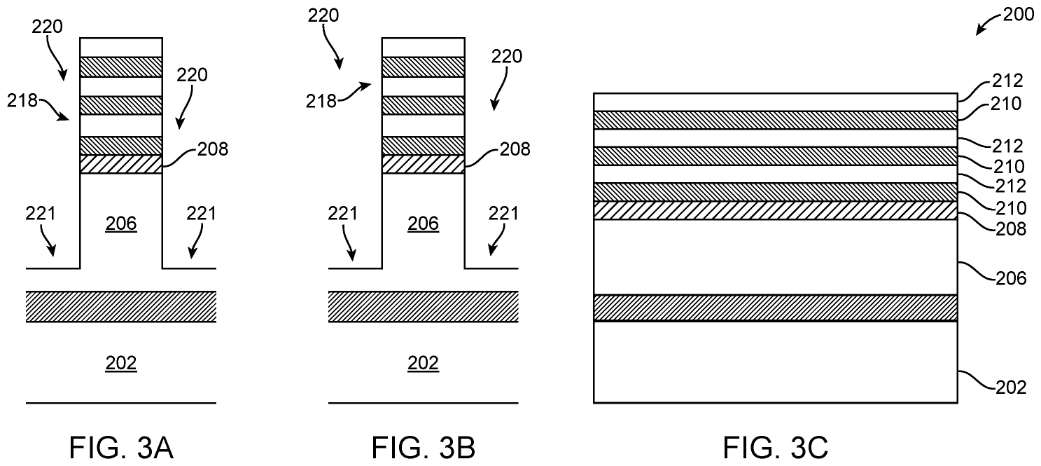

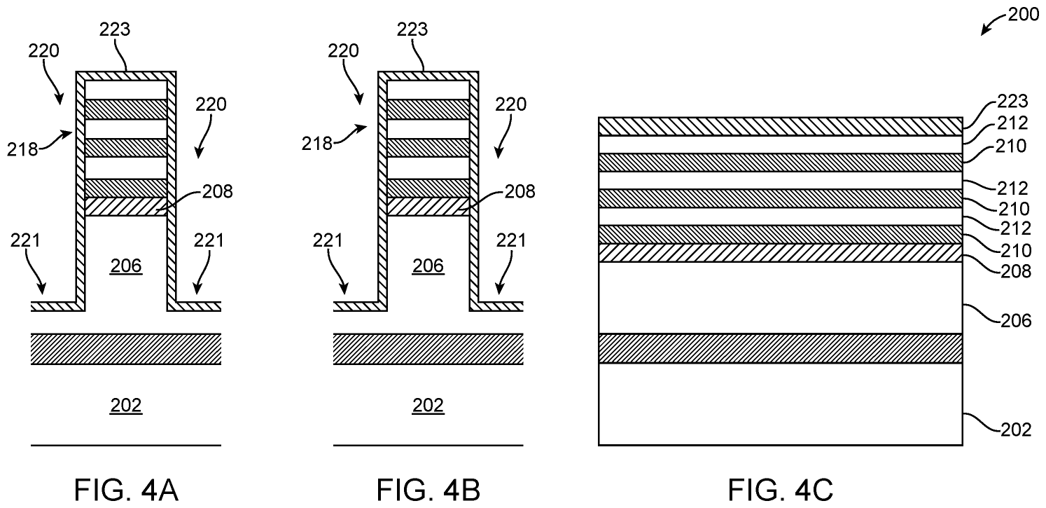

The figures described below show a fabrication process for fabricating a semiconductor device 200 having a self-aligned backside contact integration. In particular, figures described below show the semiconductor device 200 at various stages in the process, with each figure building on the previous figure. For example, FIGS. 3A, 3B and 3C show the semiconductor device 200 of FIG. 2 after subsequent fabrication operations have been performed, FIGS. 4A-4C show the semiconductor device 200 of FIG. 3 after subsequent fabrication operations have been performed, and so on. Additionally, figures that share the same number (e.g., FIG. 4A, FIG. 4B, and FIG. 4C) show the semiconductor device at the same point in time. In other words, each figure that shares a number shows the various views of the semiconductor device after the same set of fabrication operations have been performed.

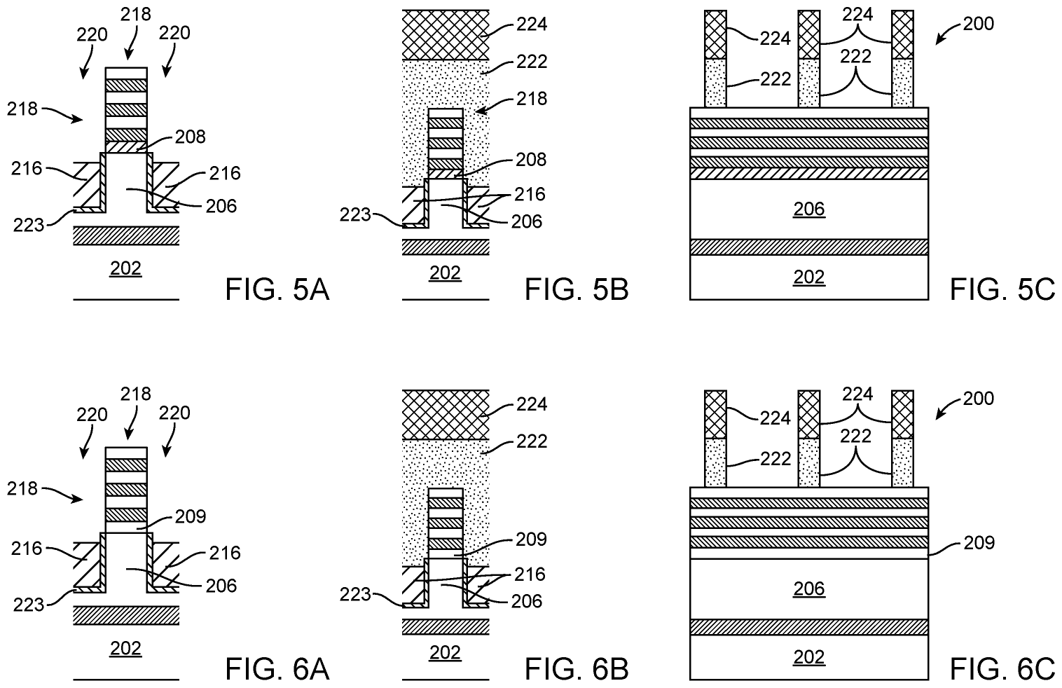

Furthermore, figures having the same letter following the number show the same cross-sectional cut at different stages. In particular, the figures that end in ‘A” (e.g., FIG. 3A, FIG. 4A, FIG. 5A, FIG. 6A, etc.) show cross-section views along the Y1 cut (i.e., the inter-gate region or active region) as the fabrication process proceeds. Likewise, figures that end in ‘B’ (e.g., FIG. 3B, FIG. 4B, FIG. 5B, FIG. 6B, etc.) show cross-sectional views along the Y2 cut (i.e., the gate region), and figures that end in ‘C’ (e.g., FIG. 3C, FIG. 4C, FIG. 5C, FIG. 6C, etc.) show cross-sectional views along the X cut at the various stages.

Referring now to FIG. 2, a cross-sectional view of an example semiconductor device 200 at an intermediate stage in the fabrication process is illustrated in accordance with embodiments of the present disclosure. The semiconductor device 200 is illustrated after the formation of an initial, or starting, semiconductor stack on a wafer. The semiconductor stack comprises a first sacrificial layer 204 deposited on top of a substrate 202. The first sacrificial layer 204 may be, for example, a sacrificial low-Ge % SiGe such as, for example, SiGe30%. The first sacrificial layer 204 will act as an etch stop when removing the substrate 202 in subsequent fabrication operations. As such, in some embodiments, the first sacrificial layer 204 may be BOX SiO2 if the starting wafer is a SOI wafer.

A semiconductor (e.g., Si) layer 206 (e.g., a Si epitaxy layer) is deposited on top of the first sacrificial layer 204. A second sacrificial layer 208 is then deposited on top of the semiconductor layer 206. The second sacrificial layer 208 may be a sacrificial high-Ge % SiGe layer such as, for example, SiGe55%.

Alternating layers of a third sacrificial material 210 and a semiconductor material 212 (e.g., Si) may then be stacked on top of the second sacrificial material layer. The third sacrificial material 210 may be a sacrificial low-Ge % SiGe such as, for example, SiGe30%. The layers of the semiconductor material 212 will end up being the nanosheet layers that make up the semiconductor channel for the semiconductor device 200.

Referring to FIGS. 3A, 3B, and 3C, the semiconductor device 200 is illustrated after creating the nanosheet stack 218, and forming a hardmask 214 on a portion of the stack 218. After depositing the hardmask 214 on the semiconductor device 200, the nanosheet stack 218 may be patterned. Patterning the nanosheet stack 218 may include performing, for example, an extreme ultraviolet lithography (EUV) and/or an RIE operation to create one or more nanosheet structures (referred to herein as fins 218). The trenches 220 expose sidewalls of the underlying semiconductor layer 206 along with STI regions 221 of the substrate semiconductor layer 206 located below the second sacrificial layer 208 and lateral to the fins 218.

Turning to FIGS. 4A, 4B, and 4C, the semiconductor device 200 is illustrated after depositing a shallow trench isolation (STI) liner 223. The STI liner 223 is formed on an upper surface of the STI regions 221 and on the sidewalls of the semiconductor layer 206 located beneath the fins 218. The STI liner 223 is formed from an insulative material and can be deposited using various depositing process such as, for example, low pressure chemical vapor deposition (LPCVD) or plasma enhanced chemical vapor deposition (PECVD). The insulative material includes, but is not limited to, silicon nitride (SiN), and has a thickness ranging, for example, from about 3 nm to about 12 nm.

In FIGS. 5A, 5B and 5C, the semiconductor device 200 is illustrated after forming a shallow trench isolation (STI) layer 216 in each of the STI regions 221. The STI layer 216 may prevent electric current leakage between the adjacent semiconductor components (e.g., between adjacent nanosheet FETs). In some embodiments, the STI layer 216 may be an oxide material. After forming the STI layers 216, the hardmasks 214 can be removed to expose the upper surface of the fins 218.

With continued references to FIGS. 5B and 5C, one or more dummy gates 222 are formed on the semiconductor device 200. The dummy gate 222 can be formed in the gate region along cut Y2, as shown in FIG. 5B. The dummy gate 222 can be made of any suitable material as would be recognized by a person of ordinary skill in the art. In one or more non-limiting embodiments of the present disclosure, the dummy gate 222 can include a thin layer of silicon oxide (SiO2) followed by deposition of a bulk amorphous silicon (a-Si). A hardmask 224 can then be formed on top of the dummy gates 222, which serves to pattern the dummy gates 222, prevent damage and/or undesired material deposition that may occur in subsequent fabrications processes.

Turning to FIGS. 6A, 6B and 6C, the semiconductor device 200 is illustrated after selectively removing the second sacrificial layer 208. In one or more non-limiting embodiments of the present disclosure, forming the second sacrificial layer 208 from a sacrificial high-Ge % SiGe material allows it to be selectively removed without removing the third sacrificial material 210. As shown in FIGS. 6A, 6B and 6C, the second sacrificial layer 208 can be removed from the entire semiconductor device 200, including the inter-gate region (shown in FIG. 6A), the gate region (shown in FIG. 6B), and the nanosheet region (shown in FIG. 6C). Accordingly, a void 209 is formed between the fin 218 and the semiconductor layer 206.

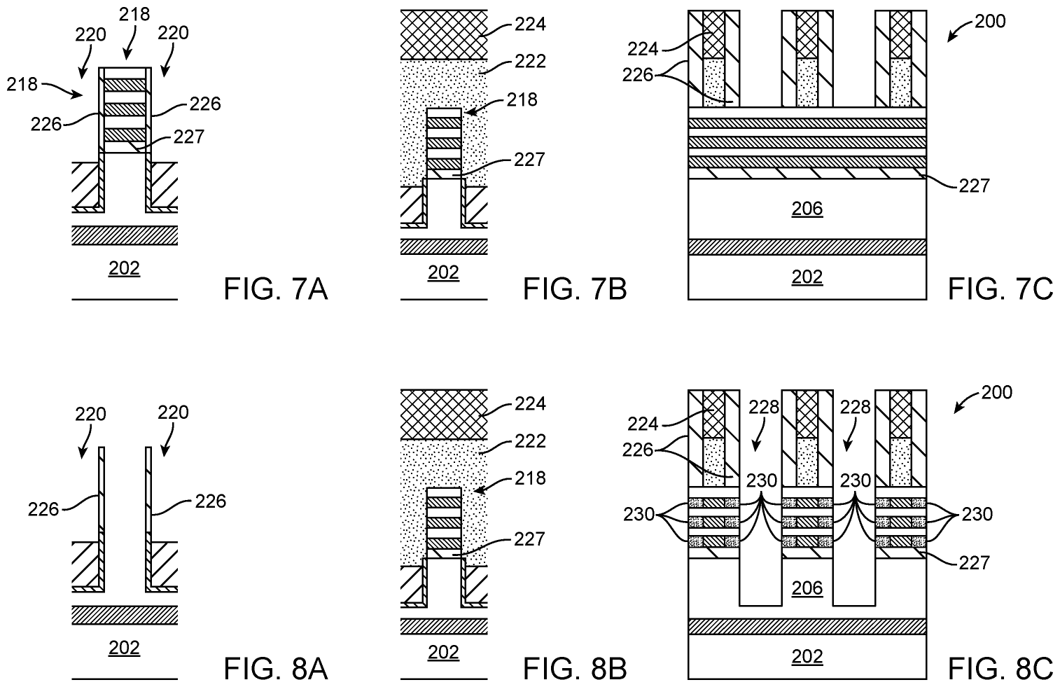

Referring to FIGS. 7A, 7B and 7C, the semiconductor device 200 is illustrated after forming one or more spacer layers 226. One or more of the spacer layers 226 can include a self-aligned substrate isolation (SASI) layer 227 and one or more sidewall spacers. The SASI layer 227 can include a portion of the spacer layers 226 that sits between the semiconductor layer 206 and the fins 218. The SASI layer 227 can be deposited where the second sacrificial layer 208 was previously found, as shown in FIGS. 7A and 7B. Additionally, the spacer sidewalls 226 can be deposited along the walls of the exposed fins 218, as shown in FIG. 7A, as well as along the sidewalls of the dummy gates 222 and the hardmask 224, as shown in FIG. 7C.

The spacer layers can be made out of, for example, SiO2, SiOCN, SiOC, SiBCN. The spacer layers 226 can be deposited on the semiconductor device 200 after removal of the second sacrificial layer 208. In some embodiments, a spacer reactive ion etch (RIE) operation can be performed to remove the spacer layer 226 from on top of the STIs 216 and the fins 218.

After forming the one or more spacer layers 226, FIGS. 8A, 8B and 8C illustrated the semiconductor device 200 after performing a nanosheet recess operation. The nanosheet recess operation can include performing a selective etching operation that removes a portion of the fins 218 and a portion of the semiconductor layer 206 below remaining portions of the fins 218. Accordingly, a plurality of trenches 228 are formed as shown in FIGS. 8A and 8C. The spacer sidewalls 226 and the STI 216, however, are largely unaffected by the selective etching operation (e.g., due to the selected materials used to form the fins 218, the sidewalls 226 and the STI 216). In one or more non-limiting embodiments, the spacer sidewalls 226 can be slightly etched such that it is slightly shorter and/or thinner than prior to etching, as can be seen in FIG. 8C (e.g., the top of the spacer 226 is no longer coplanar with the top of the hardmask 224). A result of the selective etching is that the sidewalls of the STI 216 and a top of the semiconductor layer 206 between the STI layers 216 are exposed.

In FIG. 8C, the hardmask 224 and the spacer layers 226 serve to largely protect the remaining portions of the fins 218 located below the hardmask 224 and the spacer layers 226, while a portion of the fins 218 between the spacer layers 226 are etched down into the semiconductor layer 206. However, the recess operation (or a subsequent SiGe indentation operation) does result in exposed portions of the third sacrificial layers 210 in the trenches 228 being partially etched back. An inner spacer 230 is then formed where the third sacrificial layers 210 were etched back. The inner spacer 230 can be formed from various spacer materials including, but not limited to, SiO2, SiOCN, SiOC, SiBCN.

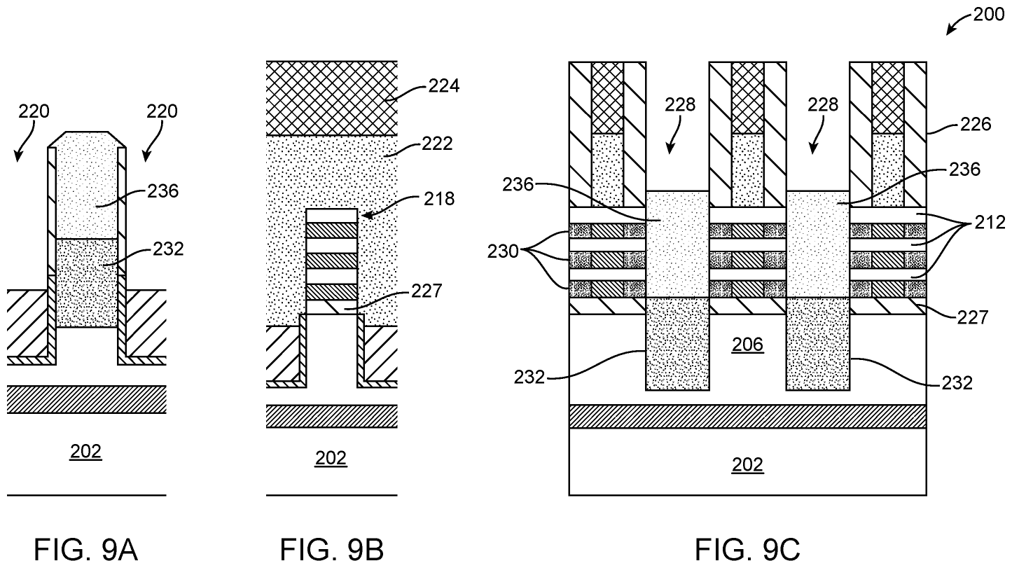

Referring to FIGS. 9A, 9B and 9C, the semiconductor device 200 is illustrated after performing a bottom-up epitaxy growth process to from sacrificial placeholders 232. The epitaxy growth process includes epitaxially growing a semiconductor material such as SiGe, for example, which grows faster in the “100” direction compared to the “110” direction. Accordingly, the sacrificial placeholders holders 232 are formed in the trenches 228 between the spacer sidewalls 226 shown in FIG. 9A, as well as in the trenches 228 between the remaining portions of the fins 218 in the nanosheet region as shown in FIG. 9C. A cyclic epi-etch back process may be used to ensure that the epi growth from exposed sidewalls of nanosheets can be suppressed.

With continued reference to FIGS. 9A and 9C, source/drains 236 are epitaxially grown on the upper surface of the sacrificial placeholders holders 232. A similar process used to form the sacrificial place holder 232 can be performed to grow the source/drains 236. As shown in FIG. 9A, the source/drain epitaxy 236 overtops the sidewall spacers 226 in the inter-gate region. Furthermore, as shown in FIG. 9C, the source/drain epitaxy 236 extends above the top of the fins 218. In other words, the top surface of the source/drain epitaxy 236 is above the top of the uppermost Si layer 212.

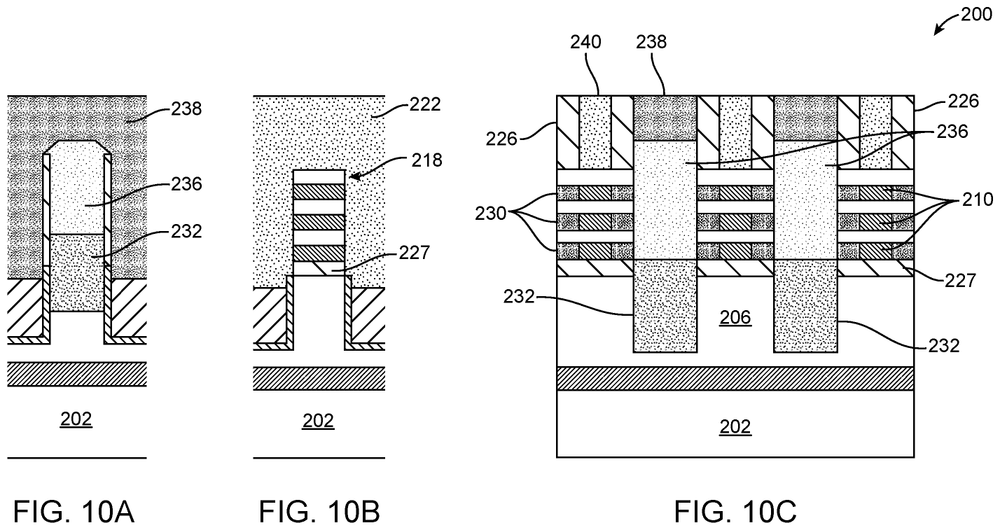

Turning now to FIGS. 10A, 10B and 10C, the semiconductor device 200 is illustrated after depositing an inter-layer dielectric (ILD) 238. The material used for the ILD 238 can include various oxide or insulating (i.e., non-conductive) materials. The ILD 238 may surround and cover the source/drain epitaxy 236, the STI 216, and the spacer sidewalls 226 shown in FIG. 10A. Likewise, the ILD 238 can fill in the rest of the trenches 228 as shown in FIG. 10C.

The ILD 238 can include any suitable material(s) known in the art, such as, for example, porous silicates, carbon doped oxides, silicon dioxides, silicon nitrides, silicon oxynitrides, or other dielectric materials. The ILD 238 can be formed using any method known in the art, such as, for example, chemical vapor deposition, plasma enhanced chemical vapor deposition, atomic layer deposition, or physical vapor deposition.

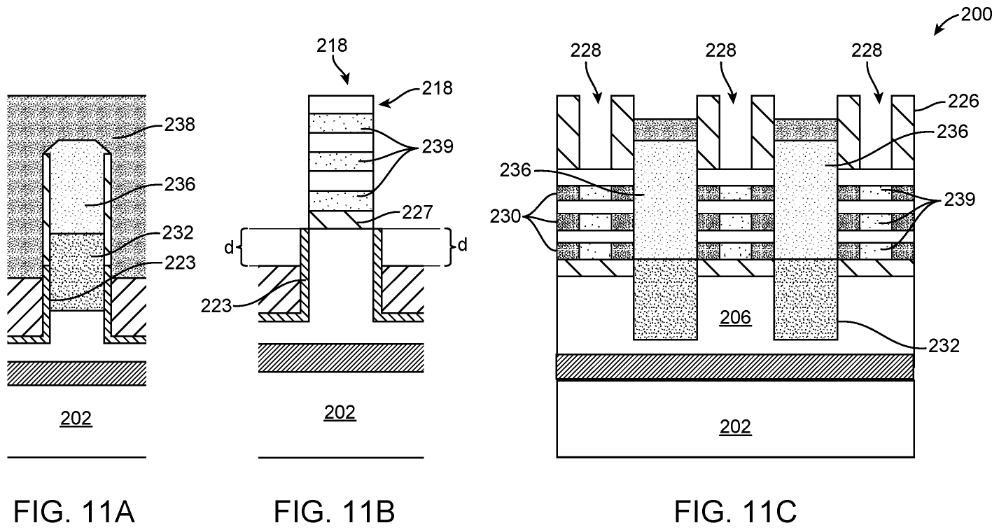

Following deposition of the ILD 238, a chemical-mechanical planarization (CMP) process can be performed. The planarization process can expose the top portions of the ILD 238, the sidewall spacers 226, and the dummy gate 222, as shown in FIG. 11C.

Referring to FIGS. 11A, 11B and 11C, the semiconductor device 200 is illustrated following removal of the dummy gate 222 and after releasing the remaining third sacrificial material 210 to form voids 239. In some embodiments of the present disclosure, a combination of a partial dry etch and partial wet etch is performed to remove the dummy gate 222 and release the remaining third sacrificial material 210. In other embodiments of the present disclosure, the dummy gate 222 and the remaining third sacrificial material 210 can be removed using a full dry etch scheme.

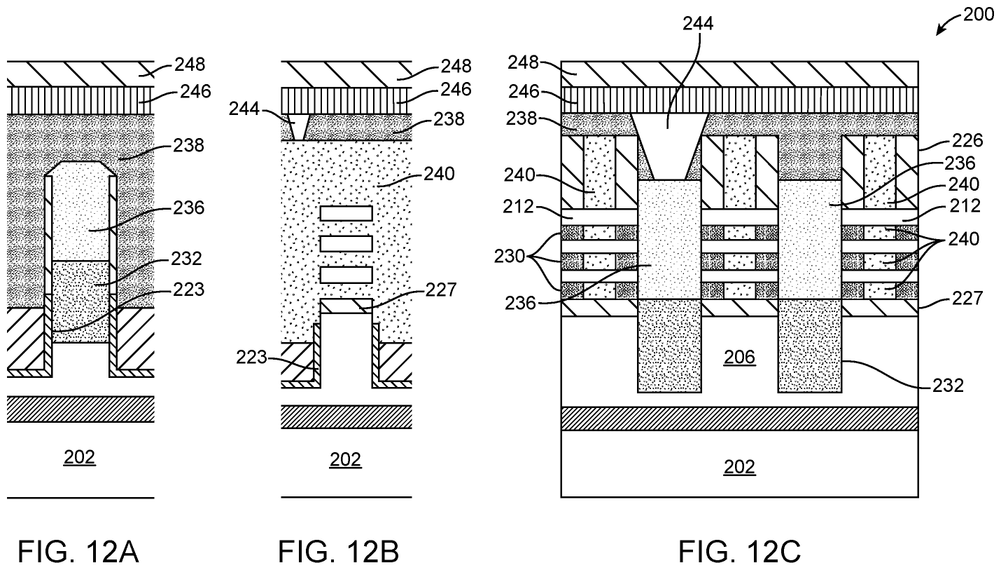

Referring now to FIGS. 12A, 12B and 12C, the semiconductor device 200 is illustrated following formation of a high-k metal gate (HKMG) 240. Formation of the HKMG 240 includes deposing a HKMG material that surrounds the remaining semiconductor material 212 of the fin 218 and fills the voids 239. In other words, during this stage, a replacement HKMG 240 is formed in place of the dummy gate 222 and SiGe layers 210. The HKMG 240 includes the high-k dielectric such as HfO2, ZrO, HfLaOx, HfAlOx, etc., and workfunction metal (WFM) such as TiN, TiC, TiAlC, TiAl, etc. and it may further comprise optional low resistance conducting metals such as W, Co and Ru. Those skilled in the art will recognize that a “replacement metal gate” refers to a gate, which replaces a previously formed dummy gate (also referred to herein as a sacrificial gate, a non-active gate, or a non-gate) and becomes an active component of the semiconductor structure 200.

The work function metal can comprise a metal selected so as to have a specific work function appropriate for a given type FET (e.g., an N-type FET or a P-type FET). For example, for a silicon-based N-type FET, the work function metal can comprise hafnium, zirconium, titanium, tantalum, aluminum, or alloys thereof, such as hafnium carbide, zirconium carbide, titanium carbide, tantalum carbide, or aluminum carbide, so that the work function metal has a work function similar to that of N-doped polysilicon. For a silicon-based P-type FET, the work function metal can comprise, for example, ruthenium, palladium, platinum, cobalt, or nickel, or a metal oxide (e.g., aluminum carbon oxide or aluminum titanium carbon oxide) or a metal nitride (e.g., titanium nitride, titanium silicon nitride, tantalum silicon nitride, titanium aluminum nitride, or tantalum aluminum nitride) so that the work function metal has a work function similar to that of P-doped polysilicon.

With continued reference to FIGS. 12A, 12B, and 12C, one or more middle-of-line (MOL) structures 244 and one or more back-end-of-line (BEOL) structures 246 are formed on the ILD layer 238. The MOL structures include one or more epitaxy and/or gate contacts 244, as well as another ILD layer 238 deposited on top of the semiconductor device 200 (e.g., as shown in FIG. 12B, in which an ILD layer 238 is on top of the metal gate 240). The epitaxy contacts 244 may be made out of any suitable material including, for example, a silicide liner at bottom of the contact such as Ti, Ni, NiTi, NiPt, and a conductive metal such as Ru or W, or Co, with a thin adhesion metal liner such as TiN. The BEOL structure 246 can include a number of interconnects or other structures. Following formation of the MOL structures 244 and BEOL structures 246, the semiconductor device 200 is bonded to a carrier wafer 248.

It is to be understood that the dimensions of the MOL 244 and BEOL 246 structures, as well as the carrier wafer 248, are not necessarily drawn to scale. The MOL 244 and BEOL 246 structures and the carrier wafer 248 may be formed using any suitable processes, as would be recognized by a person of ordinary skill in the art. In some embodiments, BEOL 246 and carrier wafer 248 may be pre-fabricated and then bonded with the semiconductor device 200.

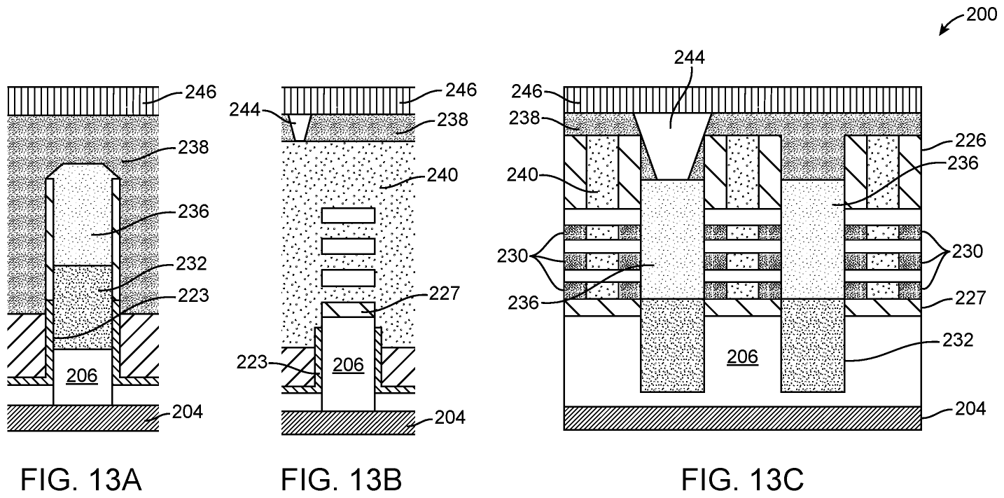

Referring to FIGS. 13A, 13B and 13C, the substrate 202 is removed from the semiconductor device 200. When removing the substrate 202, the first sacrificial layer 204, can serve as an etch stop. Accordingly, the substrate 202 can be removed through a selective etching process that stops on the first sacrificial layer 204.

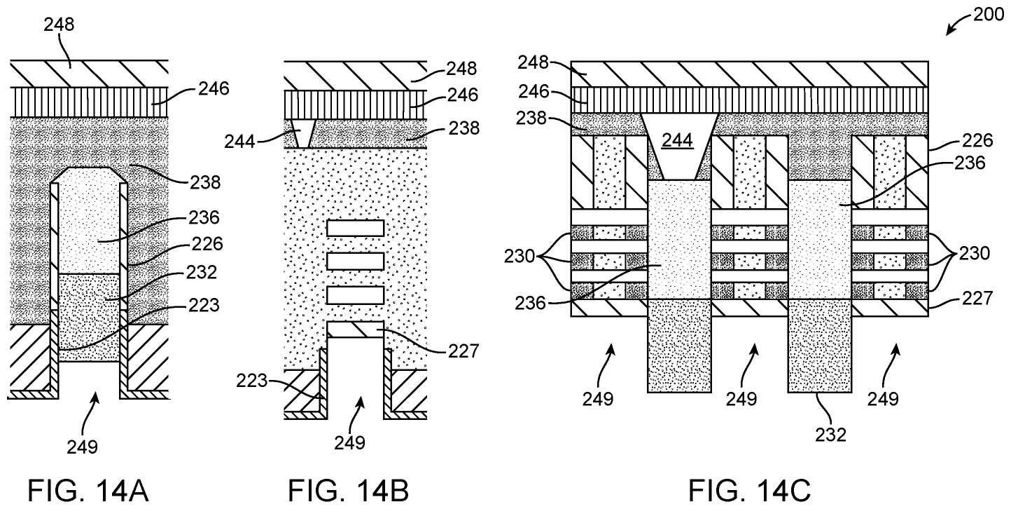

Turning now to FIGS. 14A, 14B and 14C, a etch process is performed to remove the first sacrificial layer 204 (i.e., the etch stop) and the semiconductor layer 206. In one or more non-limiting embodiments of the present disclosure, a first etching process can be performed to remove the first sacrificial layer selected to the semiconductor layer 206. Once, the semiconductor layer 206 is exposed, a subsequent second etching process is performed to remove the semiconductor layer 206. In one or more non-limiting embodiments, the second etching process is selective to the STI liner 223, the sacrificial epitaxy placeholders 232, and the SASI layer 227. Selective removal of the semiconductor layer 206 forms trenches 249 that expose the sacrificial epitaxy placeholders 232 and the SASI layer 227. As described herein, the STI liner 223 protects the STI 216 layers from being recessed when removing the semiconductor layer 206 during the selective etching process as shown in FIGS. 14A and 14B. In addition, the STI liner 223 protects the HKMG 240 from being recessed as further shown in FIG. 14B. As a result, the STI liner 223 prevents over-etching of the STI layer 216 when removing the semiconductor layer 206. The STI liner 223 also serves to control the height of the STI layer 216 during subsequent etching processes and prevents the formation of a self-aligned backside contact near the HKMG 240. In this manner, the backside contact to gate short concerns that exist when forming known backside contacts can be avoided.

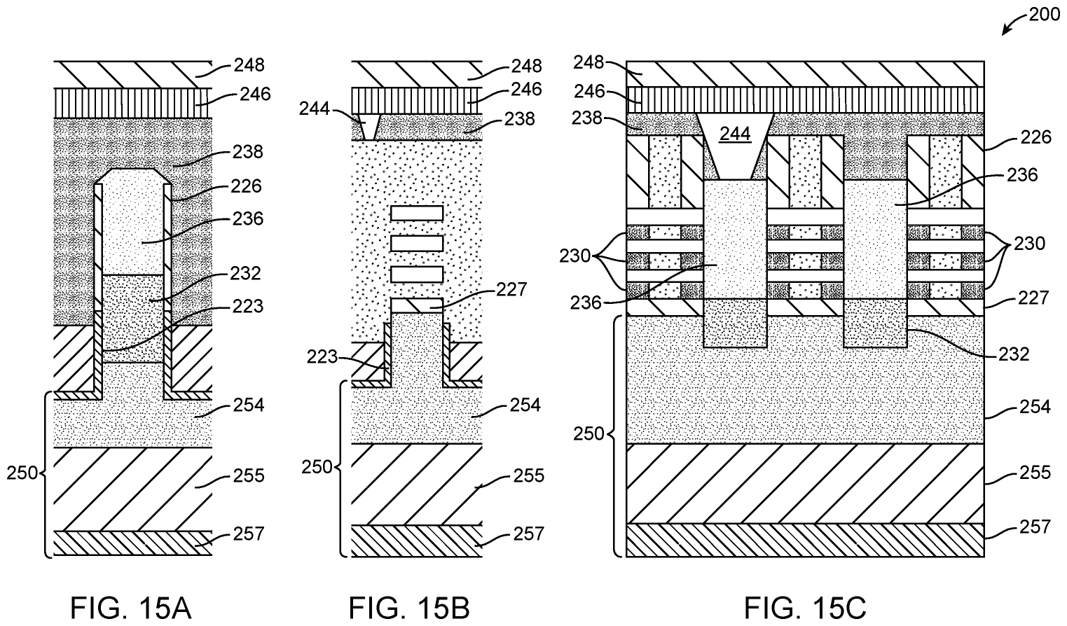

Turning now to FIGS. 15A, 15B and 15C, a backside patterning stack 250 is formed on the backside of the semiconductor device 200. Accordingly, the backside patterning stack 250 replaces a portion of the semiconductor substrate 206 covering the STI liner 223 and the sacrificial epitaxy placeholders 232. The backside patterning stack 250 includes a backside ILD 254, an organic planarization layer (OPL) 255, and a lithography (i.e., “litho”) etch barrier layer 257. The ILD 254 fill can be deposited on top of and around the STI liner 223 (see FIGS. 15A and 15B), along with the epitaxy placeholders 232, and the SASI 226 (see FIG. 15C). The backside ILD can include various oxide or insulating materials and can be deposited using, for example, a plasma-enhanced chemical vapor deposition (PECVD) process. The OPL 255 can be formed using spin-on coating or other suitable processing such as spin-on processes, although low temperature CVD amorphous carbon (a-C) could also be used. The OPL 255 may be formed of or using a precursor such as polyacrylate resin, epoxy resin, phenol resin, polyamide resin, polyimide resin, unsaturated polyester resin, polyphenylenether resin, polyphenylenesulfide resin, benzocyclobutene (BCB), etc. More generally, the OPL 255 may be formed of a-C with a certain amount of non-metallic, non-Si elements. The OPL 255 may have a height or vertical thickness in the range of about 30 to 200 nm. The etch barrier layer 257 can include a silicon containing anti-reflective coating (SiARC) material and can be deposing using a SOC process. An additional photoresist material can be formed on top of the etch barrier layer 257, using spin-on coating or other suitable processing such as spin-on processes, during following etch patterning process (not shown in FIGS. 15A, 15B, and 15C). The etch barrier layer 257 can serve as a resist control during optical imaging while also acting as an etch barrier to manage etch patterning.

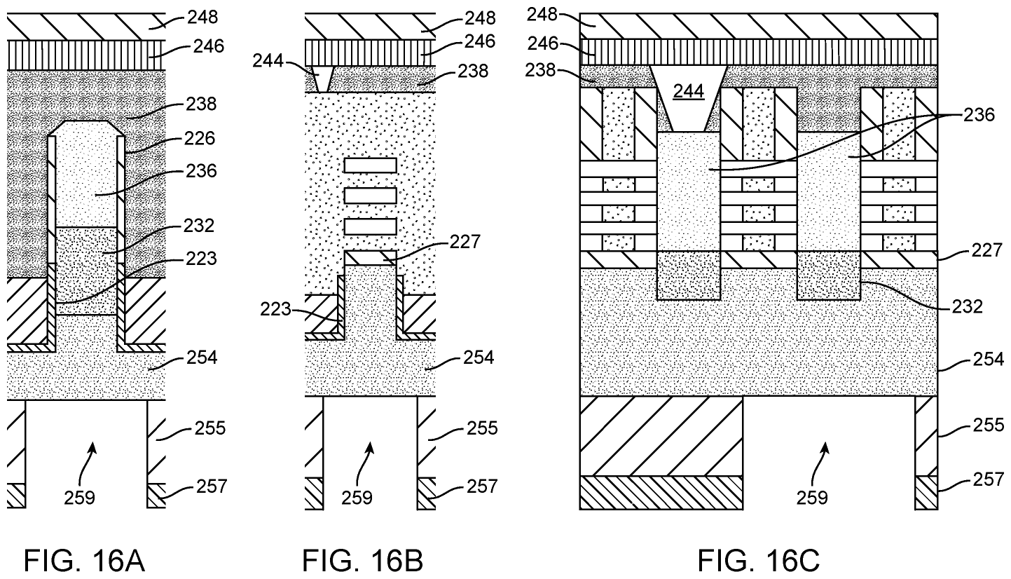

Referring to FIGS. 16A, 16B, and 16C, the semiconductor device 200 is illustrated after patterning the etch barrier layer 257 and the OPL 255. According to a non-limiting embodiment of the present disclosure, a selective RIE process can be performed to etch the etch barrier layer 257 and the OPL layer 255 with respect to the backslide ILD 254. In this manner, a pattern of openings 259 can be formed in the OPL 255 to expose targeted portions of the backside ILD 254.

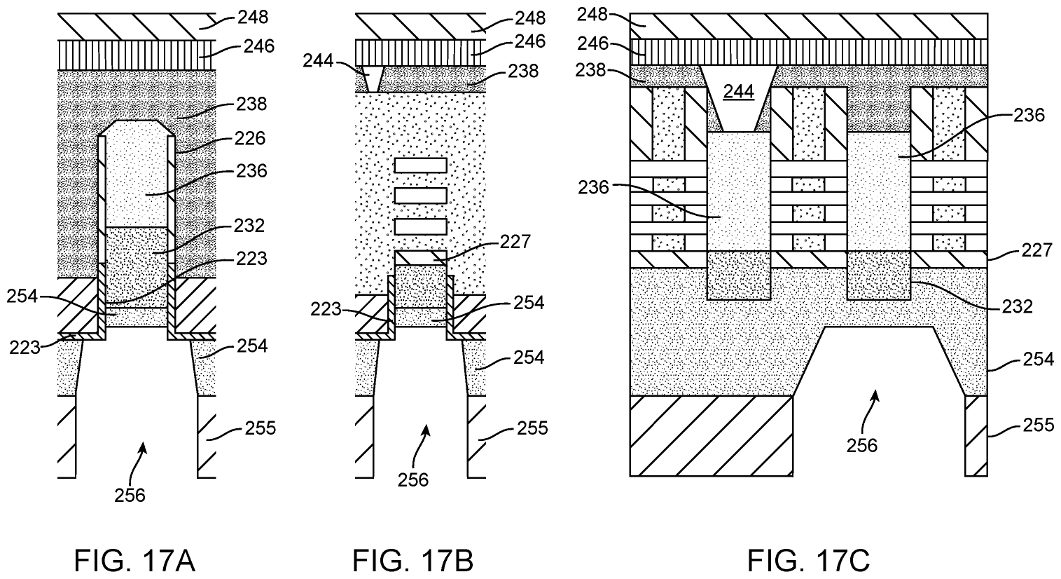

FIGS. 17A, 17B and 17C illustrate the semiconductor device 200 after performing a first stage backside contact patterning process. The first stage backside contact patterning process includes performing a first selective RIE to form backside contact trenches 256 into the ILD 254 without etching the STI liner 223. In this manner, a portion of the backside ILD 254 can be etched above the STI layers 216 since they are not protected by the STI liners 223.

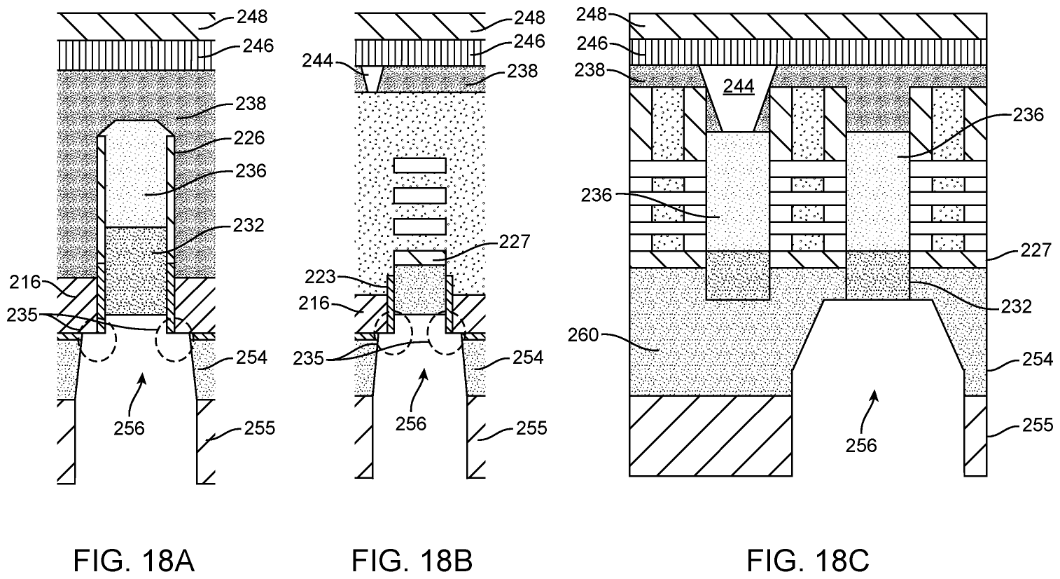

Turning now to FIGS. 18A, 18B and 18C, the semiconductor device 200 is illustrated following a second stage backside contact patterning process. The second stage backside contact patterning process includes performing a second selective RIE to selectively etch exposed portions of the STI liner 223 without etching the underlying STI layers 216 to form liner opening 235. Accordingly, a portion of the STI layers 216 are exposed (see FIGS. 18A and 18B) by the liner openings 235, along with the backside surface of the epitaxial placeholders 232 (see FIGS. 18A and 18C).

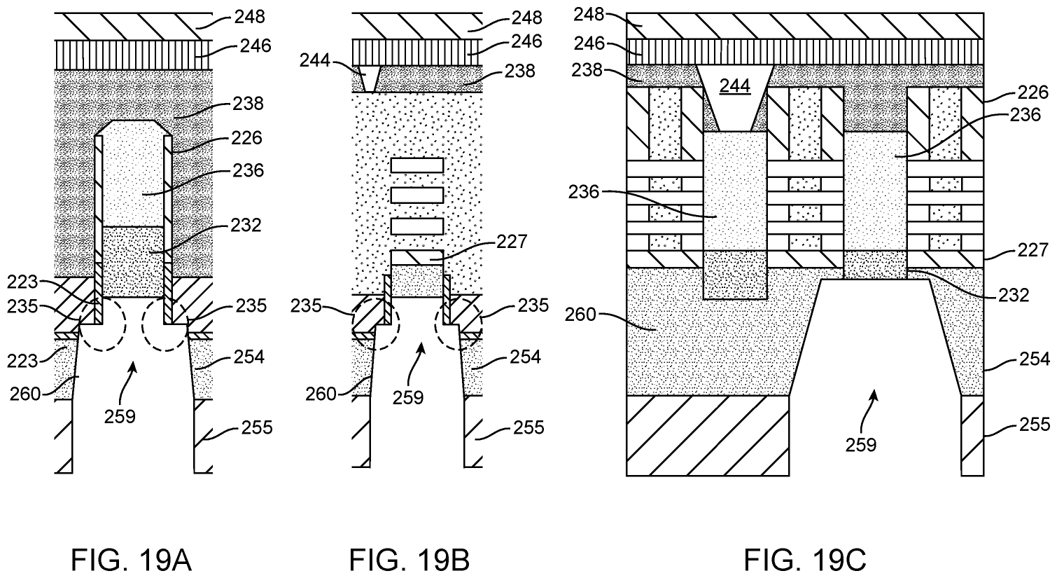

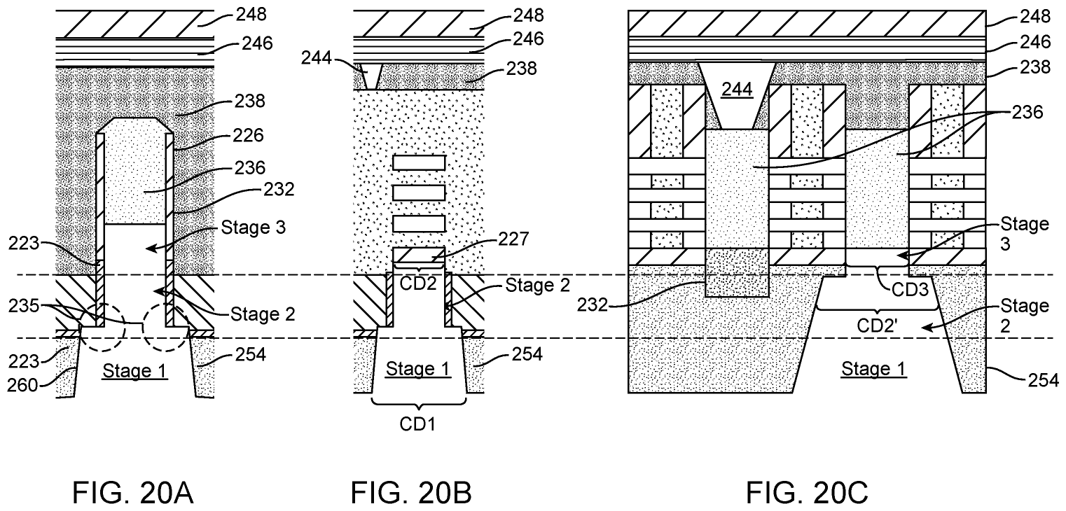

Referring to FIGS. 19A, 19B and 19C, the semiconductor device 200 is illustrated following a third stage backside contact patterning process. The third stage backside contact patterning process includes performing a third non-selective RIE to over etch the exposed portions of the STI liner 223, a portion of the STI layers 216 and targeted portions of the backside ILD 254 (see FIGS. 19A and 19B) and the backside surface of the epitaxial placeholders 232 to ensure good landing for all placeholders 232 (see FIGS. 19A and 19C). After completing the third stage backside contact patterning process, the OPL 255 can be stripped from the backside ILD 254 as shown in FIGS. 20A, 20B and 20C.

Because the contact trenches 256 are formed by performing a contact patterning stage on top of the STI liners 223 (see FIGS. 17A and 17B) and then performing additional contact patterning stages on top of the sacrificial epitaxy placeholders 232 before removing the placeholders 232, the resulting contact trenches 256 are formed as three-stage trenches. That is, The first stage trench and the second stage trench have aligned edges cross-gate view (e.g., in the X-view), but displacement in Y2—view, and the first stage trench has a larger critical dimension (CD1) compared to the second stage trench (CD2). The second stage trench and the third stage trench are confined by STI layer 216 (e.g., the size of the second stage trench and the third stage trench are similar in Y1 and Y2 views), but in the cross-gate view (X-view), second stage trench has larger size than the third stage trench (CD2′>CD3) in the X-view, i.e., along the cross-gate cut.

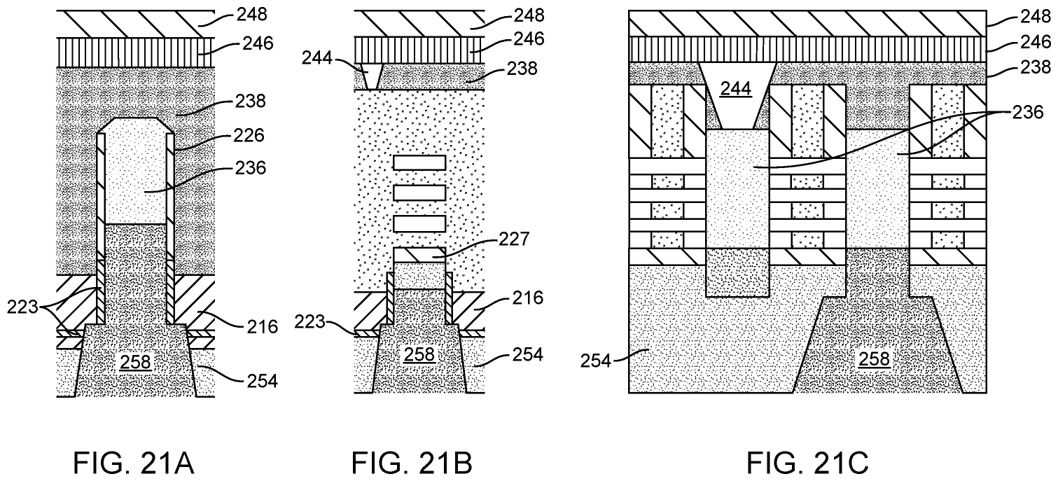

In FIGS. 21A, 21B and 21C, the semiconductor device 200 is illustrated after forming multi-stage backside contacts 258 in the contact trenches 256. The multi-stage backside contacts 258 can be formed of any suitable conductive material such as, a silicide liner at bottom of the contact such as Ti, Ni, NiTi, NiPt, and conductive metal such as Ru or W, or Co, with a thin adhesion metal liner such as TiN. In at least one non-limiting embodiment of the present disclosure, the trenches 256 can be overfilled with the conductive material, and a CMP process can be performed so that the upper surface of the multi-stage backside contacts 258 are co-planar with the upper surface of the backside ILD 254.

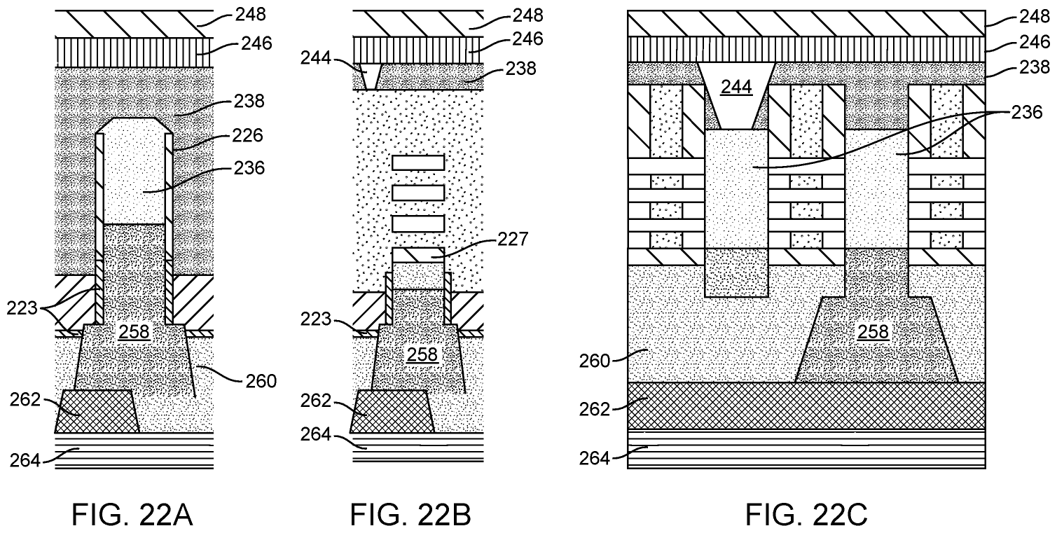

Turning now to FIGS. 22A, 22B, 22C, the semiconductor device 200 is illustrated after formation of one or more electrically conductive backside power delivery elements. The backside power delivery elements include, but are not limited to, one or more backside power rails (BPRs) 262 and a backside power distribution network (BSPDN) 264. The BSPDN 264 can include a network of low-resistive metal wires, which provides power supply and reference voltage (i.e., VDD and VSS) to the semiconductor device 100. Accordingly, one or more BPRs 262 can establish an electrically conductive path between the BSPDN 264 and the backside contact 258.

The BPRs 262 can be formed by first depositing a power-level ILD 260 on the backside ILD 254, and then forming the BPRs 262 in the power-level ILD 260. In one or more non-limiting embodiments of the present disclosure, the BPRs 262 can include a Vss and a Vdd BPR 262. The Vdd BPR 262 may be formed at least partially on a surface of the backside contact 258, as shown in FIGS. 21A and 21C. The BSPDN 264 is then formed on the BPRs 262.

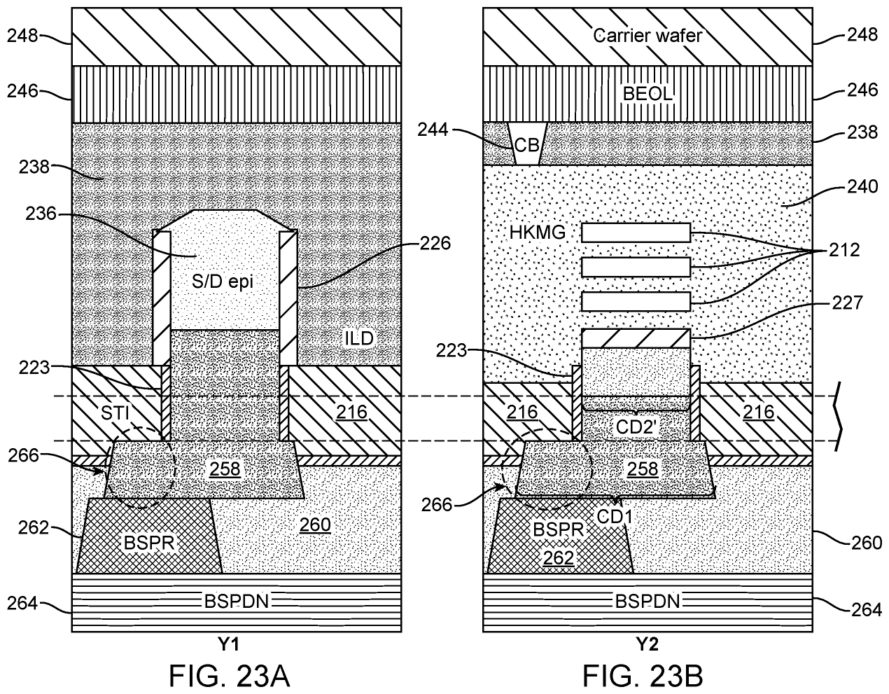

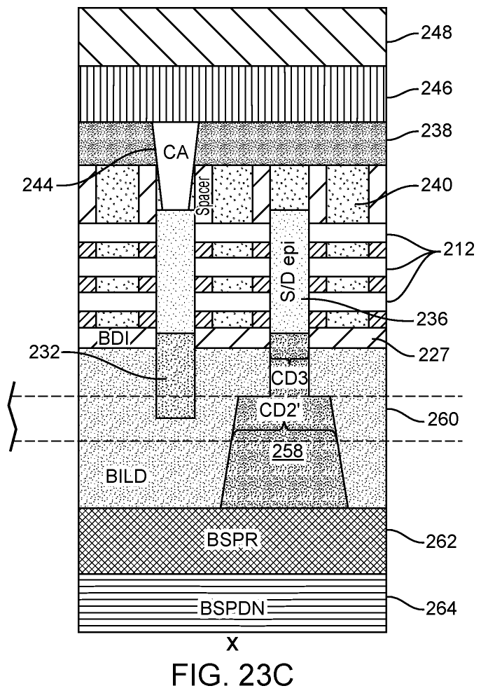

With reference to FIGS. 23A, 23B and 23C, a semiconductor device 200 fabricated according to the process flow described herein is illustrated according to a non-limited embodiment of the present disclosure. As described herein, the multi-stage trench patterning process results in a multi-stage backside contact 258 which avoids the backside contact to gate short concerns associated with conventional backside contacts. For instance, the first stage contact portion and the second stage contact portion have aligned edges cross-gate view (e.g., in the X-view), but displacement in Y2—view. In addition, the first stage contact portion has a larger critical dimension (CD1) compared to the second stage contact portion (CD2′). The second stage contact portion and the third stage contact portion are also confined by STI layer 216 (e.g., the size of the second stage trench and the third stage trench are similar in Y1 and Y2 views), but in the cross-gate view (X-view) the second stage contact portion has larger size than the third stage trench (CD2′>CD3) in the X-view, i.e., along the cross-gate cut.

With continued reference to FIGS. 23A and 23B, the multi-stage backside contact 258 further includes an overlap portion 266. The overlap portion 266 extends laterally from the multi-stage backside contact 258 and overlaps the STI layer 216. In a non-limiting embodiment of the present invention, the overlap portion 266 is interposed between an STI layer 216 and the BSPR 262. The final dimensions of the STI layer 216 can include a vertical thickness or height ranging from about 50 nm to about 150 nm. In one or more non-limiting embodiments of the present invention, the vertical thickness of the overlap portion 266 is smaller than the vertical thickness of a combination of the first stage and the second stage of the multi-stage backside contact 258. The controlled thickness of the STI layer 216 achieved using the STI liners 223 allows for an increased distance between the overlap portion 266 and the metal gate 240 compared to conventional backside contacts. Accordingly, the backside contact can be arranged further away from the metal gate to mitigate and avoid the gate short concerns associated with conventional backside contacts.

In one or more non-limiting embodiments of the present disclosure, the overlap portion 266 extends laterally from a first side of the multi-stage backside contact 258 at a greater distance compared to the opposite side of the multi-stage backside contact 258. Accordingly, the overlap portion 266 increases the contact area between the multi-stage backside contact and the BSPR 262 which reduced contact resistance while also avoiding the backside contact to gate short concerns associated with conventional backside contacts.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of fabricating a semiconductor device, the method comprising:
etching a semiconductor substrate to form a semiconductor fin between shallow trench isolation (STI) regions;
forming a STI liner on an upper surface of the STI regions and on sidewalls of the semiconductor fin;
etching a portion of the semiconductor fin to exposed a portion of the semiconductor substrate defining source/drain regions;
forming backside contact placeholders in the source/drain regions and on the exposed portion of the semiconductor substrate, and forming source/drains on an upper surface of the backside contact placeholders;
forming a gate over a remaining portion of the semiconductor fin;
replacing a portion of the semiconductor substrate covering the backside contact placeholders and the STI liner with a backside patterning stack;
performing a multi-stage backside contact patterning process to selectively remove portions of the backside patterning stack without removing the STI liner to form a multi-stage backside contact trench; and
filling the multi-stage backside contact trench with a conductive material to form a multi-stage backside contact.

2. The method of claim 1, wherein performing the multi-stage backside contact patterning process comprises:
performing a first stage etch to selectively form the multi-stage backside contact trench in a backside inter-layer dielectric (ILD) included in the backside patterning stack without etching the STI liner;
performing a second stage etch to remove portions of the STI liner exposed by the multi-stage backside contact trench and expose portions of an STI layer; and
performing a third stage etch to recess a portion of the exposed STI layer.

3. The method according to claim 2, wherein:
wherein below the gate, a first portion of a first stage trench of the multi-stage backside contact trench has a greater CD than a first portion of a second stage trench of the multi-stage backside contact trench,
wherein below the source/drain, a second portion of the second stage trench has the same CD as a first portion of a third stage trench of the multi-stage backside contact trench, and
wherein the third portion of the second stage trench extends below the semiconductor fin and has a greater CD than a second portion of the third stage trench which extends into the source/drain region.

4. The method according to claim 3, wherein filling the multi-stage backside contact trench comprises:
removing at least one of the backside contact placeholders to extend the multi-stage backside contact trench into the source/drain region; and
filling the multi-stage backside contact trench with the conductive material such that the multi-stage backside contact makes contact with the source/drain.

5. The method of claim 4, wherein filling the multi-stage backside contact trench with the conductive material forms an overlap portion of the multi-stage backside contact which extends laterally therefrom and overlaps the STI layer.

6. The method according to claim 5, wherein a first stage of the multi-stage backside contact has a larger critical dimension compared to a second stage of the multi-stage backside contact, and the second stage of the multi-stage backside contact has a larger size than a third stage of the multi-stage backside contact.

7. The method of claim 6, further comprising forming an electrically conductive backside power delivery element on the multi-stage backside contact trench.

8. The method of claim 7, wherein the overlap portion contacts the backside power rail.

9. The method of claim 8, further comprising forming a backside power distribution network on the electrically conductive backside power delivery element, wherein the electrically conductive backside power delivery element is a backside power rail backside power rail.

10. A semiconductor device comprising:
a semiconductor substrate including shallow trench isolation (STI) regions and a semiconductor fin between the STI regions;
a STI liner on an upper surface of the STI regions, and a STI layer in each of the STI regions, the STI liner including a liner opening exposing a portion of the STI layer;
a source/drain on a sidewall of the semiconductor fin; and
a multi-stage backside contact on the source/drain and contacting the portion of the STI layer via the liner opening.

11. The semiconductor device of claim 10, wherein the multi-stage backside contact includes an overlap portion.

12. The semiconductor device of claim 11, wherein the overlap portion extends laterally from the multi-stage backside contact and overlaps the STI layer.

13. The semiconductor device according to claim 12, further comprising a gate surrounding the semiconductor fin,
wherein below the gate, a first portion of a first stage trench of the multi-stage backside contact trench has a greater CD than a first portion of a second stage trench of the multi-stage backside contact trench,
wherein below the source/drain, a second portion of the second stage trench has the same CD as a first portion of a third stage trench of the multi-stage backside contact trench, and
wherein the third portion of the second stage trench extends below the semiconductor fin and has a greater CD than a second portion of the third stage trench which extends into the source/drain region.

14. The semiconductor device of claim 13, further comprising forming an electrically conductive backside power delivery element on the multi-stage backside contact.

15. The semiconductor device of claim 14, wherein the overlap portion is between the STI layer and the backside power delivery element.

16. The semiconductor device of claim 15, wherein the electrically conductive backside power delivery element is a backside power rail.

17. The semiconductor device of claim 16, wherein the overlap portion contacts the backside power rail.

18. The semiconductor device of 17, further comprising forming a backside power distribution network on the backside power rail.

19. The semiconductor device of 18, wherein the backside power distribution network, the backside power rail, and the multi-stage backside contact comprise an electrically conductive material.

20. The semiconductor device of claim 11, wherein a vertical thickness of the overlap portion is smaller than a vertical thickness of a combination of the first stage and the second stage of the multi-stage backside contact.
